(19) United States
(12) Patent Application Publication
(10) Pub. No.: US 2019/0035906 A1
(43) Pub. Date: Jan. 31, 2019

(54) Field Effect Transistor and Method for Manufacturing Same

(71) Applicant: National Institute of Advanced Industrial Science and Technology, Tokyo (JP)

(72) Inventor: Isao Inoue, Tsukuba-shi (JP)

(21) Appl. No.: 16/073,148

(22) PCT Filed: Jan. 18, 2017
(86) PCT No.: PCT/JP2017/001543

§ 371 Date: Jul. 26, 2018

(30) Foreign Application Priority Data
Jan. 27, 2016 (JP) 2016-013743

(51) Int. Cl. H01L 29/51; H01L 29/78; H01L 29/24; H01L 29/04; H01L 29/66; H01L 21/02; H01L 21/311; H01L 49/00

(52) U.S. Cl. CPC H01L 29/513; H01L 29/78; H01L 29/24; H01L 29/045; H01L 29/517; H01L 49/003; H01L 21/02118; H01L 21/02181; H01L 21/31127; H01L 21/31144; H01L 29/66969

(57) ABSTRACT

Provided is a field effect transistor (FET) including a gate insulating film with a laminated (two-layer) structure having more improved characteristics for practical use. The FET includes a perovskite-type structure single-crystalline composite oxide substrate 1 that forms a channel layer; and a gate insulating film with a laminated structure in which para-xylylene polymer films 4 and 5 and hafnium oxide 6 are laminated in this order on the single-crystalline composite oxide substrate 1.

### TECHNICAL FIELD

The present invention relates to a field effect transistor (FET) and a method for manufacturing the field effect transistor and more specifically relates to the FET configured to use Mott transition and its manufacturing method.

### BACKGROUND ART

In a conventional FET in which a semiconductor such as silicon is used for its channel layer, if degree of its integration increases according to miniaturization such as reduction of channel length for performance improvement, the number of dopants in a channel decreases accordingly. For example, if the volume of the semiconductor for the channel decreases to about 20 nm×20 nm×5 nm, only about 10 dopants (that is, about 10 carriers) are included in it on average. If the number of carriers is as small as above, variation of characteristics among devices is serious and causes a major problem that impairs the reliability.

To solve such problems with the conventional semiconductor FET, a FET (a Mott FET) configured to use some phase transitions as “Mott metal-to-insulator transition” appearing in the strongly electron correlated materials, has been under development. The Mott transition is a metal-to-insulator phase transition in which a material that is originally a metal turns into an insulator called a Mott insulator due to the strong electron correlations. Even if the Mott insulator is miniaturized to about 20 nm×20 nm×5 nm as above, tens of thousands to hundreds of thousands of carriers still exist in it. Thus, the problems such as carrier-number limitation on its miniaturization do not exist.

However, if a gate insulating film with a high dielectric constant (high-k) metal oxide which is frequently used in the conventional FET is formed on a surface of a thin film or a single crystal of the Mott insulator, constituent elements of the gate insulating film migrate in the Mott insulator through the surface defects of the Mott insulator, and a deficient oxide layer is formed at an interface between them. The secondary oxide layer like this is a huge obstacle for application of the Mott FET, since it may contain a very large number of trap levels and it is very difficult to control its characteristics. Moreover, the secondary oxide like this is often a normal oxide semiconductor different from a strongly correlated oxide which induces the Mott transition, and makes it impossible to show an expected property of the Mott FET such as drastic change of conductivity of the channel.

Under such circumstances, the present inventor has proposed a FET including a gate insulating film with a laminated structure of a para-xylylene polymer film and tantalum oxide for improving characteristics of the interface between the Mott insulator and the gate insulating film (Japanese Patent No. 5522688).

### CITATION LIST

### Patent Literature

Japanese Patent No. 5522688

### SUMMARY OF INVENTION

With regard to the FET of Japanese Patent No. 5522688, it has been shown that surface charge density, carrier mobility in the channel and leakage current are improved even though a strontium titanate which is very prone to surface defects is used for the channel, and the gate insulating film having the laminated structure configured by the para-xylylene polymer film and the tantalum oxide is usable for the Mott FET which is prone to the defects like the strontium titanate.

However, a metal mask is required to form the FET, so that reducing the size of the FET is difficult. There is still room for further improvement or betterment for practical use, such as the film thickness of the para-xylylene polymer film and that of the tantalum oxide film (e.g., the para-xylylene polymer film: 80 nm, the tantalum oxide film: 250 nm).

The present invention aims to provide a FET including a gate insulating film with a laminated structure having improved characteristics for practical application, and its manufacturing method.

The present invention provides a FET including: a single-crystalline composite oxide substrate with a perovskite-type structure, forming a channel layer; and a gate insulating film with a laminated structure in which a para-xylylene polymer film and hafnium oxide are laminated in this order on the single-crystalline composite oxide substrate.

The present invention provides a method for manufacturing a FET. The manufacturing method includes steps of: (a) preparing a single-crystalline strontium titanate substrate; (b) forming the first polymer film of para-xylylene having the first thickness on the single-crystalline strontium titanate substrate; (c) forming openings to be source and drain electrodes by patterning the first polymer film; (d) forming the source and drain electrodes by forming a conductive film in the openings; (e) forming the second polymer film of para-xylylene having the second thickness on the single-crystalline strontium titanate substrate on which the source and drain electrodes were formed; (f) forming a hafnium oxide film on the second polymer film; and (g) forming a gate electrode on the second polymer film between the source and drain electrodes.

### Advantageous Effects of Invention

According to the FET of the present invention, by using the above-described laminated gate insulating film, it is possible to obtain a good-quality channel (interface) which does not have a trap or scattering due to oxygen deficiency or structural misalignment. As a result, it is possible to improve various characteristics such as carrier mobility and sheet carrier density (e.g., carrier mobility: 11 cm²/Vs, sheet carrier density: 10¹⁴/cm²). Moreover, according to the method for manufacturing the FET of the present invention, no metal mask is required to be used, and a smaller size device can be fabricated by photolithography, thus facilitating its practical application.

### BRIEF DESCRIPTION OF DRAWINGS

FIG. 1 is a plan view (a) and cross-sectional views (b) and (c) illustrating configuration of a FET according to one embodiment of the present invention, where (a) is a SEM image, (b) is a schematic diagram, and (c) is a TEM image.

FIG. 2 is a diagram illustrating steps for manufacturing the FET according to one embodiment of the present invention.

FIG. 3 is a cross-sectional view illustrating a part of the steps for manufacturing the FET according to one embodiment of the present invention.

FIG. 4 is a diagram illustrating I_{D}-V_{G} (drain current vs gate voltage) characteristics of the FET according to one embodiment of the present invention in a sub-threshold region before carrier accumulation.

FIG. 5 is a diagram illustrating σ_{□}-n_{□} (sheet conductivity vs sheet charge density of the channel) relation of the FET according to one embodiment of the present invention in a region where carriers accumulate.

FIG. 6 is the sheet carrier density n_{□} of the channel (∘) calculated from the Hall coefficient of the FET according to one embodiment of the present invention with respect to the gate voltage VG. The sheet carrier density n_{□} calculated from Gauss's law (dashed and single-dotted line) is also plotted with respect to the gate voltage V_{G} for comparison.

FIG. 7 illustrates electrostatic capacitance C_{□}^{ins} and C_{□}^{STO} in the FET according to one embodiment of the present invention.

FIG. 8 depicts an energy band diagram of the FET according to one embodiment of the present invention in a state where carriers have accumulated.

FIG. 9 shows relations between the gate voltage V_{G} and the sheet carrier density n_{□} and 1/C_{□}^{STO} for explaining that the sheet carrier density n_{□} of the channel of the FET according to one embodiment of the present invention is large.

### DESCRIPTION OF EMBODIMENTS

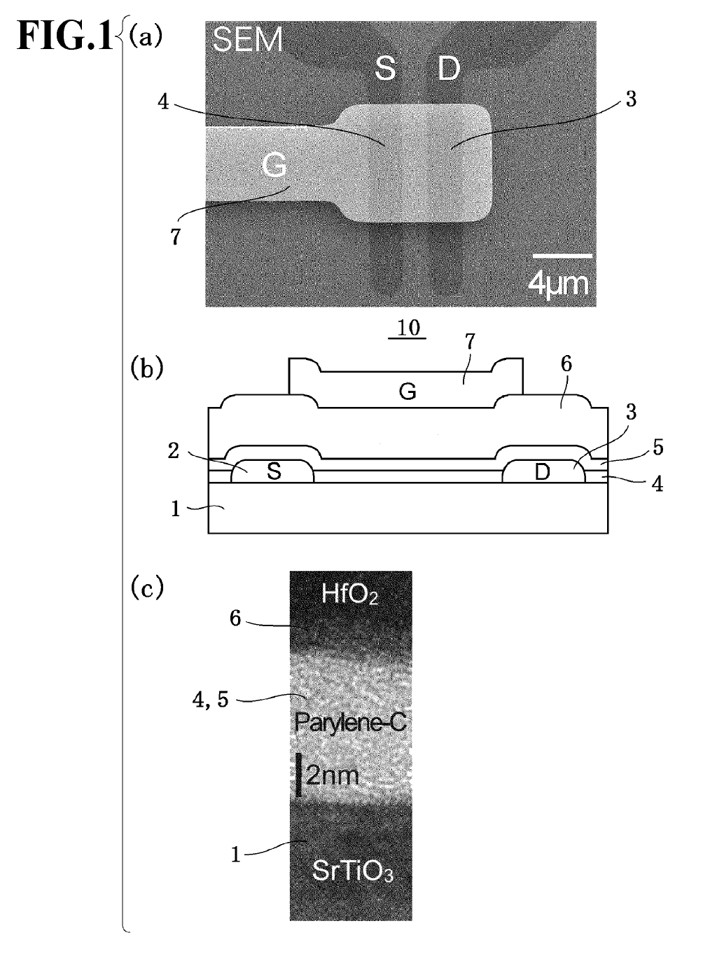

An embodiment of the present invention will be described with reference to the drawings. FIG. 1 is a diagram illustrating configuration of a FET 10 according to one embodiment of the present invention. (a) is a SEM image of an upper surface of the FET 10, (b) is a schematic diagram of a cross section of the FET 10, and (c) is a TEM image of a cross section of the FET 10. The FET 10 includes: a substrate 1 made of single-crystalline strontium titanate (SrTiO₃) which is one of perovskite-type structure single-crystalline composite oxides and forms a channel layer; a source electrode 2 and a drain electrode 3 on a surface of the substrate 1; a gate insulating layer with a two-layer structure configured by Parylene C (poly-monochloro-para-xylylene, registered trademark) (4, 5) which is one of para-xylylene polymer films, and hafnium oxide (HfO₂) 6; and a gate electrode 7. The Parylene C may be a single continuous layer. The reason why the Parylene C is illustrated as the two-layer structure in (b) of FIG. 1 will be described later.

A single-crystalline SrTiO₃ substrate having a surface tilted about 0.03 degrees from (100) (hereinafter, (100) surface for simplicity) is used for the single-crystalline SrTiO₃ substrate 1, for example. A single-crystalline SrTiO₃ substrate having a different surface such as (110) or (111) surface may also be used for it. SrTiO³ is not the Mott insulator but a transition metal oxide, and it is a band insulator (intrinsic semiconductor) which does not naturally have an electron carrier or a hole carrier. However, SrTiO₃ is a transition metal oxide with which an exceptionally pure and large single crystal can be fabricated, and a single-crystalline substrate having a flat surface at atomic level are widely supplied (commercially). In addition, SrTiO₃ is an oxide which is very prone to the formation of surface defects, and its problems regarding FET fabrication are very similar to those of the Mott insulators which is prone to the formation of surface defects. Hence, a single-crystalline SrTiO₃ substrate is used in the present invention.

A metal material such as titanium (Ti) or aluminum (Al) having a thickness of 10 nm is used for the source electrode 2 and the drain electrode 3, for example. The Parylene C (4, 5) has a thickness of 6 nm as a whole, for example. In this case, each of the lower layer 4 and the upper layer 5 may have a thickness of 3 nm, for example. One of new findings/features according to the present invention is that the thickness of the Parylene C (4, 5) can be reduced to about 6 nm. The Parylene C is deposited on a (100) surface of the single-crystalline SrTiO₃ substrate for protecting the surface of the single-crystalline SrTiO₃ which is a material that oxygen deficiency easily occurs on its surface when an electric field is applied, and the Parylene C protection prevents the surface deterioration during a photolithography process for fabricating the FET, and further prevents electro-chemical reactions or oxygen deficiency when an electric field is applied to the (100) surface for driving the completed FET.

The hafnium oxide (HfO₂) 6 may have a thickness of approximately 20 nm to 30 nm, for example. As shown in (c) of FIG. 1, the thin Parylene C with a thickness of about 6 nm exists between the single-crystalline SrTiO₃ substrate 1 and the hafnium oxide (HfO₂) 6, so that mixing of devices does not occur between the hafnium oxide (HfO₂) and the SrTiO₃ even if gate electric field is continuously applied. The gate electrode 7 on the hafnium oxide (HfO₂) 6 may be a single layer of gold (Au) or a two-layer structure configured by titanium (Ti) and gold (Au), for example.

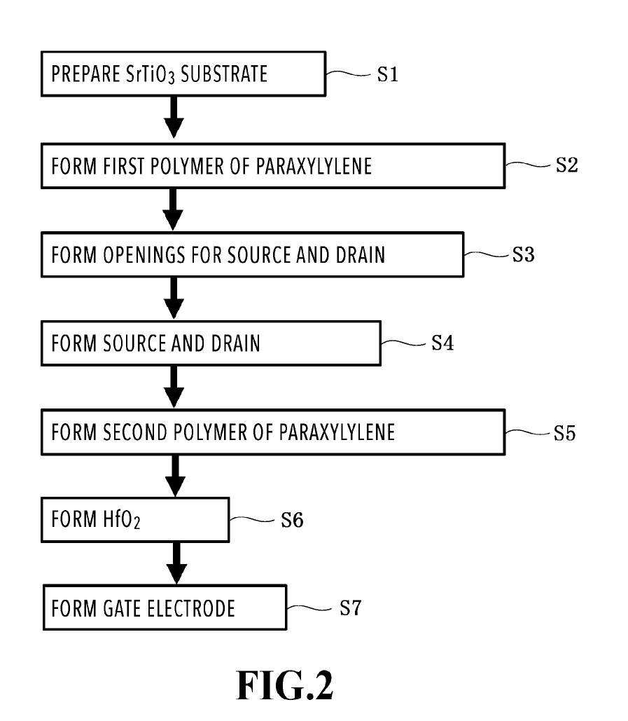

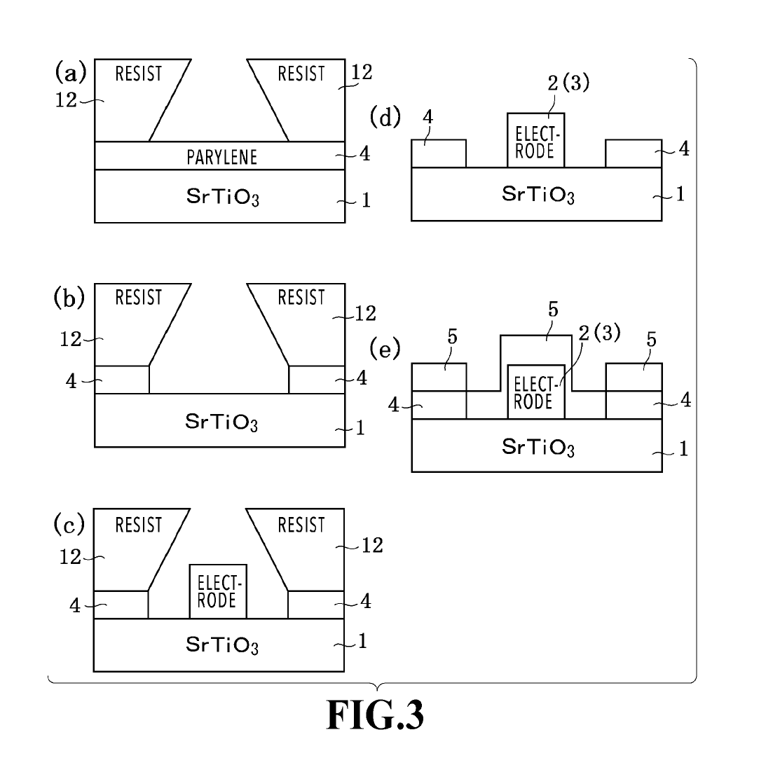

A method for manufacturing the FET 10 according to one embodiment of the present invention will be described with reference to FIGS. 2 and 3. FIG. 2 is a diagram illustrating steps for manufacturing the FET according to one embodiment of the present invention. FIG. 3 is a cross-sectional view illustrating a part of the steps for manufacturing the FET according to one embodiment of the present invention. Step S1 in FIG. 2 is a step for preparing the single-crystalline SrTiO₃ substrate 1 on which the channel of the FET is to be formed. A single-crystalline SrTiO₃ substrate having a step and terrace structure and a (100) surface with a miscut angle of 0.03 degrees or smaller is used for the single-crystalline SrTiO₃ substrate 1, for example.

Step S2 is a step for forming the first polymer film of para-xylylene having the first thickness on the surface of the single-crystalline SrTiO₃ substrate 1. Specifically, the Parylene C polymer film 4 with a thickness of 3 nm is formed as mentioned earlier, for example. For example, the forming is performed as follows. First, the single-crystalline SrTiO₃ substrate 1 is placed in a vacuum chamber which is then set to a vacuum of 5 mTorr or lower. A dimer of Parylene is heated at 135° C. to be sublimated, and its gas is passed through a furnace at 690° C. to be monomerized, and then introduced into the chamber which is maintained at a vacuum of 5 mTorr or lower. Inside the chamber, the Parylene C is polymerized at the surface of the single-crystalline SrTiO₃ substrate 1 so that the Parylene C polymer film 4 is formed. The thickness of the actually formed Parylene C is measured with a film thickness measurement apparatus F20-UV by Filmetrics Japan, Inc. and also observed by using a transmission electron microscope (TEM), for example.

Step S3 is a step for patterning the first polymer film to form openings to be the source and drain electrodes. Specifically, first, a photoresist (SIPR-9684-1.5 by Shin-Etsu Chemical Co., Ltd.) 12 is coated on the Parylene C polymer film 4. Then, the photoresist 12 on the Parylene C polymer film 4 is patterned for the source and drain electrodes by a photolithography method using an i-line stepper UTS-1700 by Ultratech, Inc. In this case, the photoresist 12 is patterned to have trapezoidal openings in cross section, in other words, openings with an undercut structure, as illustrated in (a) of FIG. 3. This is to avoid burrs sticking from an edge of each source/drain electrode (metal) to be formed later. Then, the Parylene C polymer film inside each opening is selectively removed by irradiating it with vacuum ultraviolet light within ozone plasma. One cross section after the removal of the Parylene C polymer film is illustrated in (b) of FIG. 3.

Step S4 is a step for forming the source and drain electrodes. Specifically, as illustrated in (c) of FIG. 3, vacuum vapor deposition of Ti to a thickness of 10 nm or Al to a thickness of 10 nm, for example, is performed from above the photomask 12 having the openings with the undercut structure. For Al, it is placed in an alumina crucible and vapor-deposited at 1 nm/s by resistive heating. For Ti, it is vapor-deposited at 0.1 nm/s by electron beam heating. The width of the electrode 2 (3) is determined based on the opening size of the opening at the upper end with the undercut structure. Although only one electrode is illustrated in (c) of FIG. 3, similar electrodes are formed for the source and drain electrodes. After the source and drain electrodes have been formed, the photoresist (photomask) 12 is removed by lift off. A cross section after the removal is illustrated in (d) of FIG. 3. There is a surface of the single-crystalline SrTiO₃ substrate 1, which is exposed around the electrode 2 (3).

Step S5 is a step for forming a second polymer film of para-xylylene having a second thickness on the single-crystalline SrTiO₃ substrate 1 on which the source and drain electrodes have been formed. Specifically, the Parylene C polymer film 5 with a thickness of 3 nm is formed by a similar method to step S2. In this case, as illustrated in (e) of FIG. 3, the Parylene C polymer film 5 is formed in conformal shape on the electrode 2 (3). The Parylene C polymer film is formed in step S5 in addition to step S2, because it is necessary to protect the exposed surface of the single-crystalline SrTiO₃ substrate 1 illustrated in (d) of FIG. 3. As illustrated in (b) of FIG. 1, a total thickness of the Parylene C polymer film in a region between the source electrode and the drain electrode is 6 nm as a result of these two forming steps. The Parylene C polymer film may have a thickness of approximately 6 to 10 nm in total.

Step S6 is a step for forming a hafnium oxide film (HfO₂) on the second polymer film 5. Specifically, as illustrated in (b) of FIG. 1, a thin film of HfO_{2 6} with a thickness of 20 nm is deposited using an atomic layer deposition apparatus (ALD) SUNALE R-100B by Picosun, for example. TDMAH (Hf[N(CH₃)₂]₄) may be used as a precursor of Hf in the deposition. The 20-nm thin HfO₂ film may be formed by heating the single-crystalline SrTiO₃ substrate at 120° C. in the vacuum chamber and introducing TDMAH at 130° C. and deionized purified water (H₂O) for 169 cycles. The film thickness of HfO₂ may be measured in a simple manner with a profiler AlphaStep D-100 by KLA-Tencor Corporation and also checked through the measurement with TEM, for example.

Step S7 is a step for forming a gate electrode on the second polymer film in the region between the source electrode and the drain electrode. Specifically, the gate electrode 7 may be formed in the following manner: using a photolithography method similar to step S3, a photoresist pattern of the gate electrode is formed, a 5-nm Ti film and a 500-nm Au film are vapor-deposited (the vapor deposition rate is 0.1 nm/s for Ti and 5 nm/s for Au) by electron beam heating, and then the photoresist is lifted off. In addition, moisture is removed by heating at 120° C. for one hour in the atmosphere, for example, and thereafter characteristics such as electrical conductivity is evaluated. The FET illustrated in FIG. 1 is formed by steps S1 to S7 described above.

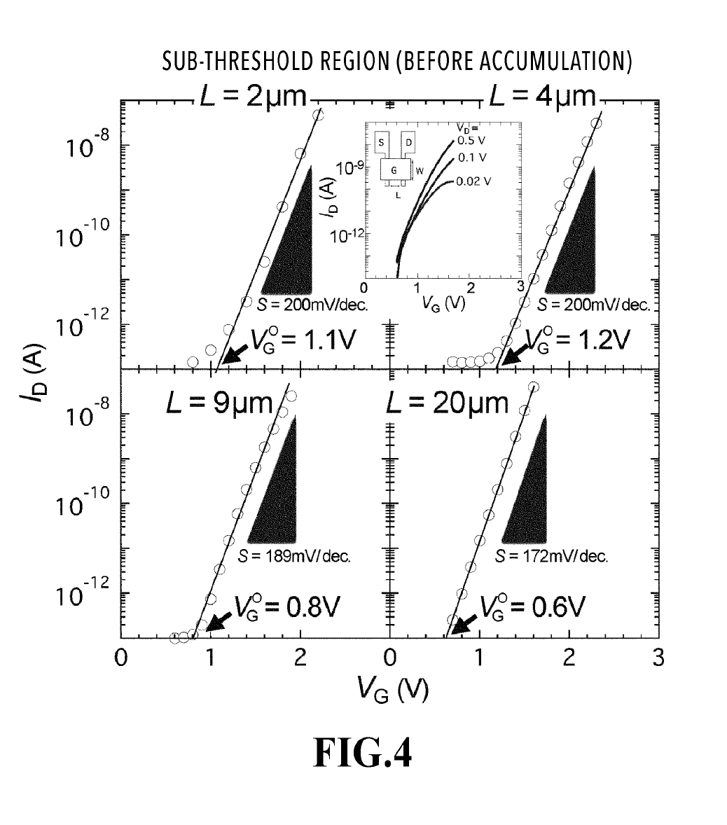

Next, the characteristics of the FET with the configuration illustrated in FIG. 1 which is actually fabricated by using the steps in FIGS. 2 and 3, will be described with reference to FIGS. 4 to 9. FIG. 4 is the I_{D}-V_{G} (drain current vs gate voltage) characteristics of the FET according to one embodiment of the present invention in a sub-threshold region before the carrier accumulation. As shown in FIG. 4, in the sub-threshold region before the carrier accumulation, a reciprocal (sub-threshold swing S) for a gradient obtained from a semi-log plot of the I_{D}-V_{G} curve is approximately 170 mV/decade (channel width L=20 μm). The theoretically smallest value of S is 60 mV/decade at room temperature. Normally, S is larger than 60 mV/decade, because electrostatic capacitance C_{□}^{STO} of the channel material per unit area is not negligibly small as compared to electrostatic capacitance C_{□}^{ins} of the gate insulator per unit area.

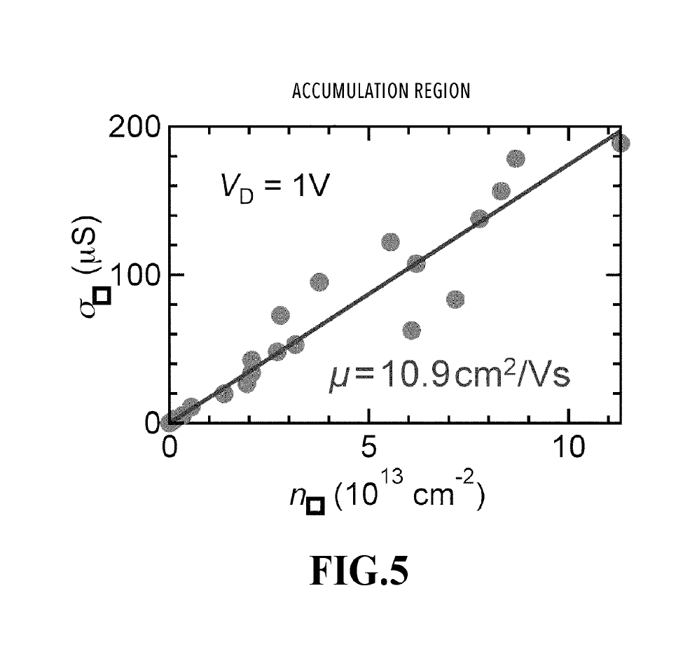

In a simple FET with a silicon channel, S at room temperature is about 100 mV/decade. There is no report that S of a FET configured by using a composite oxide such as SrTiO₃ for its channel reaches 250 mV/decade or smaller. Thus, considering that the channel is made of SrTiO_{3,} it may be seen that S of the FET fabricated this time is surprisingly small. This means that there are almost no unnecessary carriers due to oxygen deficiency and the like in the SrTiO₃ channel. Furthermore, as increasing the gate voltage applied to the SrTiO₃ channel, the channel is metalized due to an increase in accumulated carriers. Calculated carrier mobility μ at this moment is approximately 11 cm²/Vs (10.9 cm²/Vs to be precise), as shown in FIG. 5.

Here, FIG. 5 shows the σ_{□}-n_{□} (sheet conductivity vs sheet carrier density) relation of the FET according to one embodiment of the present invention in the accumulation region. Sheet carrier charge density n_{□} in FIG. 5 is derived by measuring the Hall effect. There has been no report that the carrier mobility μ of a FET configured by using a composite oxide such as SrTiO₃ for its channel, exceeds 10.9 cm²/Vs at room temperature. This indicates that the channel is close to the ideal state without a trap or scattering due to oxygen deficiency or structural misalignment.

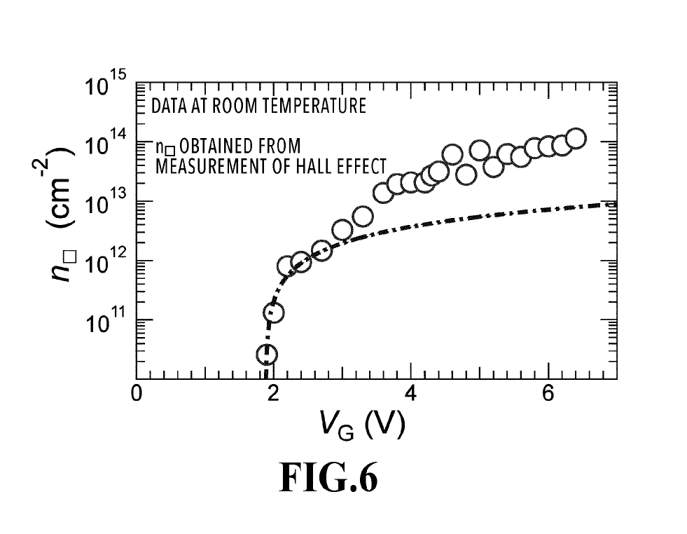

FIG. 6 is obtained by plotting the sheet carrier density nₒ (o) of the channel calculated from the Hall coefficient of the FET according to one embodiment of the present invention with respect to the gate voltage V_{G}. A relative diagram of sheet carrier density calculated from Gauss's law n_{□}=C_{□}^{ins}V_{G}/e (dashed and single-dotted line) is also plotted against the gate voltage V_{G} as a comparative example. The observed sheet carrier density reaches to the order of 10¹⁴/cm², which is approximately 10 or more times larger than the sheet carrier density calculated from Gauss's law (dashed and single-dotted line).

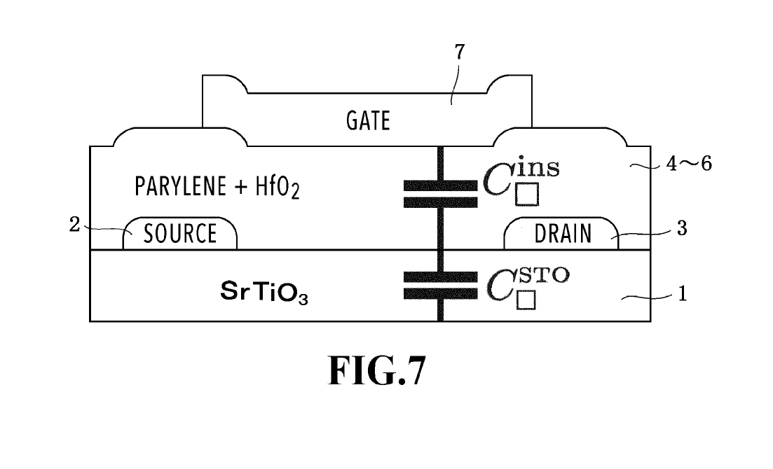

FIG. 7 is an illustrative representation of the electrostatic capacitance C_{□}^{ins} and C_{□}^{STO} in the FET according to one embodiment of the present invention. As illustrated in FIG. 7, since the electrostatic capacitance C_{□}^{ins} and C_{□}^{STO} are connected in series, C_{□}^{ins} of the Gauss's low n_{□}=C_{□}^{ins}V_{G}/e should be replaced with (1/C_{□}^{ins}+1/C_{□}^{STO})⁻¹ in actuality. However, since C_{□}^{ins}>(1/C_{□}^{ins}+1/C_{□}^{STO})⁻¹, this cannot explain the 10 or more times enhancement of the sheet carrier charge density n_{□}. It has been checked that C_{□}^{ins} remains unchanged during measurement. Hence, in order for the observed sheet carrier density nₒ to exceed that calculated from n_{□}=(1/C_{□}^{ins}+1/C_{□}^{STO})⁻¹V_{G}/e, C_{□}^{STO}<0 is necessary.

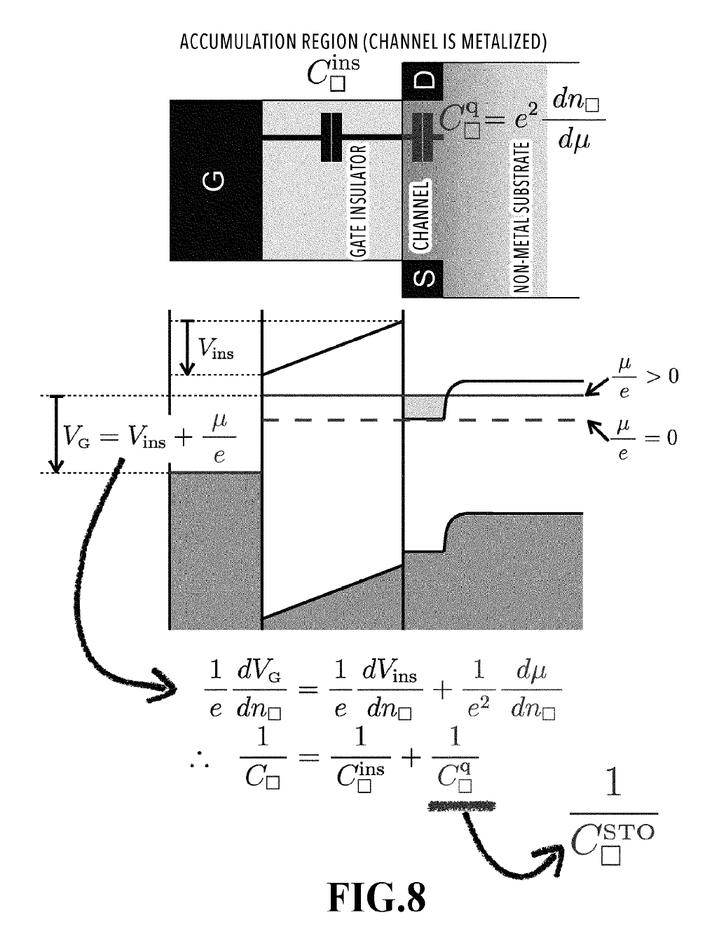

FIG. 8 illustrates an energy band diagram of the FET according to one embodiment of the present invention in the accumulation state. As illustrated in FIG. 8, both sides of a relational equation of the gate voltage V_{G} and voltage drop Vᵢₙₛ inside the gate insulator and chemical potential μ/e

V_{G}=Vᵢₙₛ+μ/e (1)

are differentiated with n_{□} to thereby obtain

$$\begin{matrix}Math . 1 & \\ \frac{1}{e} \frac{{dV}_{G}}{{dn}_{•}} = \frac{1}{e} \frac{{dV}_{ins}}{{dn}_{•}} + \frac{1}{{e}^{2}} \frac{d μ}{{dn}_{•}} . & ( 2 )\end{matrix}$$

Thus, the following is obtained.

$$\begin{matrix}Math . 2 & \\ \frac{1}{{C}_{•}} = \frac{1}{{C}_{•}^{ins}} + \frac{1}{{C}_{•}^{q}} & ( 3 )\end{matrix}$$

Here, the following holds true.

$$\begin{matrix}Math . 3 & \\ \frac{1}{{C}_{•}^{q}} = \frac{1}{{e}^{2}} \frac{d μ}{{dn}_{•}} & ( 4 )\end{matrix}$$

Then, in order for this to be negative, the following must be satisfied.

$$\begin{matrix}Math . 4 & \\ \frac{d μ}{{dn}_{•}} < 0 & ( 5 )\end{matrix}$$

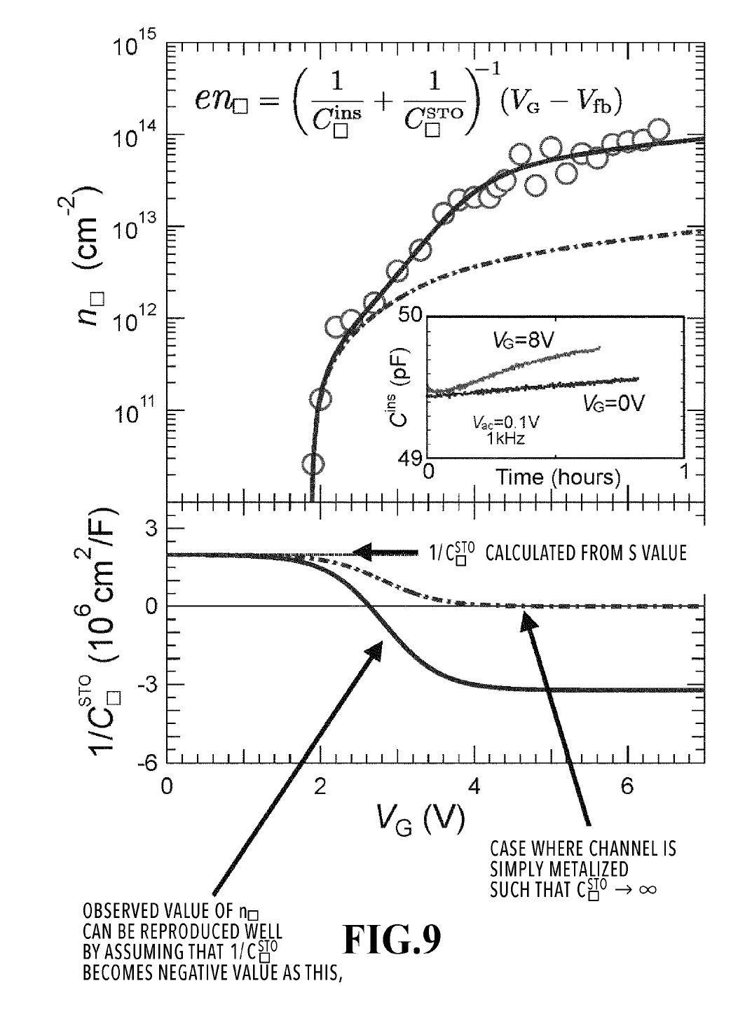

Normally, as the carrier concentration increases, the chemical potential μ/e rises. However, in a case where the density of states changes with change in carrier concentration (a case where the Mott gap is closed or the Rashba effect is present), the chemical potential may decrease. In this case, a negative electrostatic capacitance appears. FIG. 9 is a diagram illustrating the relations between the gate voltage VG and the sheet carrier density n_{□} and 1/C_{□}^{STO} for explaining the large enhancement of the sheet carrier density no of the channel of the FET according to one embodiment of the present invention. As illustrated by the lower graph (solid line) in FIG. 9, if the electrostatic capacitance of SrTiO₃ (1/C_{□}^{STO}, solid line) changes from positive values to negative values, the huge enhancement of the sheet carrier density n_{□} (white circles (∘)) plotted in FIG. 6 can be well explained, as illustrated by the upper panel of FIG. 9.

An embodiment of the present invention has been described with reference to the drawings. However, the present invention is not limited to this embodiment. Furthermore, the present invention can be carried out in modes with various modifications, corrections, and changes based on the knowledge of those skilled in the art without departing from the gist of the invention.

### INDUSTRIAL APPLICABILITY

The FET of the present invention is usable as a constituent device of various integrated circuits (IC, LSI, etc.).

### REFERENCE SIGNS LIST

1 single-crystalline strontium titanate (SrTiO₃) substrate

2, 3 source or drain electrode (source/drain electrode)

4, 5 para-xylylene polymer film (Parylene C)

6 hafnium oxide (HfO₂)

7 gate electrode

10 field effect transistor (FET)

12 photoresist (photomask)

1. A field effect transistor comprising:
a single-crystalline composite oxide substrate with a perovskite-type structure, the single-crystalline composite oxide substrate forming a channel layer; and
a gate insulating film with a laminated structure in which a para-xylylene polymer film and hafnium oxide are laminated in this order on the single-crystalline composite oxide substrate.

2. The field effect transistor according to claim 1, wherein the single-crystalline composite oxide substrate is a single-crystalline strontium titanate substrate whose surface is a (100) surface, a (110) surface, or a (111) surface.

3. The field effect transistor according to claim 1, wherein the para-xylylene polymer film includes a Parylene C film.

4. The field effect transistor according to claim 3, wherein the Parylene C film has a thickness of 6 to 10 nm, and the hafnium oxide has a thickness of 20 to 30 nm.

5. A method for manufacturing a field effect transistor comprising:
preparing a single-crystalline strontium titanate substrate;
forming a first polymer film of para-xylylene having a first thickness on the single-crystalline strontium titanate substrate;
forming openings to be a source and a drain by patterning the first polymer film;
forming the source and the drain by forming a conductive film in the openings;
forming a second polymer film of para-xylylene having a second thickness on the single-crystalline strontium titanate substrate on which the source and the drain have been formed;
forming a hafnium oxide film on the second polymer film; and
forming a gate electrode on the second polymer film between the source and the drain.

6. The manufacturing method according to claim 5, wherein the forming openings to be the source and the drain includes:
forming a photomask on the first polymer film, the photomask having openings with an undercut structure, and
removing the first polymer film in the openings with the undercut structure.

7. The manufacturing method according to claim 6, wherein the forming the source and the drain by forming a conductive film in the openings includes:
forming a conductive film on an exposed surface of the single-crystalline strontium titanate substrate inside each opening with the undercut structure, the conductive film having a width defined by a width of an upper end of said each opening with the undercut structure, and
removing the photomask.

8. The manufacturing method according to claim 7, wherein the forming the second polymer film of para-xylylene having the second thickness includes
forming the second polymer film on the exposed surface of the single-crystalline strontium titanate substrate inside said each opening with the undercut structure between the conductive film and the first polymer film.
